(19) United States
(12) Patent Application Publication
(10) Pub. No.: US 2026/0312558 A1
(43) Pub. Date: Oct. 8, 2026

(54) RADIO FREQUENCY (RF) CIRCUIT INCLUDING POWER STAGE WITH RF NOISE BLOCKING OR ATTENUATION FOR INCREASED DYNAMIC POWER RANGE

(71) Applicant: GlobalFoundries U.S. Inc., Malta, NY (US)

(72) Inventors: Ahmad Alagry, Williston, VT (US); Mustapha Slamani, South Burlington, VT (US); John Ferrario, Barre, VT (US)

(21) Appl. No.: 19/169,372

(22) Filed: Apr. 3, 2025

(51) Int. Cl. H03F 3/72; H03F 1/26; H03F 3/24

(52) U.S. Cl. CPC H03F 3/72; H03F 1/26; H03F 3/245; H03F 2200/294; H03F 2200/372; H03F 2200/451; H03F 2203/7227

(57) ABSTRACT

A radio frequency (RF) circuit includes mixer and power boosting (PB) stages and operates in a first (high power) signal mode, a second (low power) signal mode, and a blocked signal mode. The PB stage includes PB and bypass paths. The PB path can include two amplifiers in series including a first amplifier that is always on and a second amplifier switchable between on and off states depending upon the mode. By switching the second amplifier off when power boosting is disabled, RF noise leakage to the output terminal is prevented when the desired output is either a low power RF signal or no RF signal. Alternatively, instead of disabling the second amplifier to prevent RF noise leakage to the output terminal, the PB stage can include a variable attenuator either downstream of the PB and bypass paths or within the PB path downstream of the second amplifier.

### BACKGROUND

The present disclosure relates to radio frequency (RF) circuits and, more particularly, to embodiments of an RF circuit, which includes mixer and power stages and which is configured for low noise generation and a wide dynamic power range.

A radio frequency (RF) circuit (e.g., for RF applications, including millimeter wave (mmWave) wireless applications) can include a mixer. A mixer can receive an initial radio frequency input signal and a local oscillator signal and can use the received signals to generate and output a mixed radio frequency output signal. A mixer can be a down-conversion mixer (also referred to herein as down-converter) or an up-conversion mixer (also referred to herein as up-converter). In a down-converter the initial radio frequency input signal can be a high radio frequency input signal and the mixed radio frequency output signal can be a low or intermediate radio frequency output signal. In an up-converter the initial radio frequency input signal can be a low or intermediate radio frequency signal and the mixed radio frequency output signal can be a high radio frequency output signal. Additionally, some RF circuits can include both a mixer stage and a power stage downstream of the mixer stage. The mixer stage can be a mixer, as described above. The power stage can include both a power boosting path to boost the power level of the mixed radio frequency signal when needed and a bypass path to maintain the power level of the mixed radio frequency signal when needed.

### SUMMARY

Disclosed herein are embodiments of a radio frequency (RF) circuit including a power stage downstream of a mixer stage. In each of the embodiments, RF noise abatement features (e.g., features that limit or attenuate RF noise) can be selectively employed in the power stage depending upon the operating mode of the RF circuit.

More specifically, an embodiment of an RF circuit disclosed herein can include a mixer stage and a power stage downstream of the mixer stage. The power stage can include an input terminal (which is connected to the mixer stage) and an output terminal (which is connected, for example, to a device under test (DUT)). The power stage can a power boosting path. The power boosting path can include a first amplifier and a second amplifier connected in series. The power stage can also include a bypass path. The power stage can also include first and second power stage switches, which are concurrently operable to connect opposite ends of either the power boosting path or the bypass path to the input terminal and the output terminal, respectively, depending upon the operating mode of the RF circuit. In this embodiment, RF noise abatement can be achieved whenever the power boosting path is disconnected from the input and output terminals by disabling the second amplifier and, thereby limiting RF noise generation from the second amplifier.

Another embodiment of an RF circuit disclosed herein can include a mixer stage and a power stage downstream of the mixer stage. The power stage can include: an input terminal (which is connected to the mixer stage); an intermediate node; and an output terminal. The power boosting stage can further include; a power boosting path with an amplifier; and a bypass path. The power boosting stage can further include first and second power stage switches, which are concurrently operable to connect opposite ends of either the power boosting path and the bypass path to the input terminal and the intermediate node, respectively, depending upon the operating mode of the RF circuit. The power stage can further include a variable attenuator connected between the intermediate node and the output terminal. In this embodiment, RF noise abatement can be achieved whenever the power boosting path is disconnected from the input and output terminals by selectively changing the attenuation state of the variable attenuator and, thereby attenuating any RF noise generation from the amplifier.

Yet another embodiments of an RF circuit disclosed herein can include a mixer stage and a power stage downstream of the mixer stage. The power stage can include an input terminal (which is connected to the mixer stage) and an output terminal (which is connected, for example, to a device under test (DUT)). The power stage can a power boosting path. The power boosting path can include a first amplifier, a second amplifier, and a variable attenuator connected in series. The power stage can also include a bypass path. The power stage can also include first and second power stage switches, which are concurrently operable to connect opposite ends of either the power boosting path or the bypass path to the input terminal and the output terminal, respectively, depending upon the operating mode of the RF circuit. In this embodiment, RF noise abatement can be achieved whenever the power boosting path is disconnected from the input and output terminals by selectively changing the attenuation state of the variable attenuator and, thereby attenuating any RF noise generation from the amplifier.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A-1C are schematic diagrams illustrating an RF circuit in different operating modes, respectively;

FIGS. 2A-2C are schematic diagrams illustrating a disclosed embodiment of an RF circuit in different operating modes, respectively;

FIG. 3 is a schematic diagram illustrating one example of a technique for maintaining a first amplifier of the RF circuit of FIGS. 2A-2C in an always on state while selectively switching a second amplifier between on and off states;

FIGS. 4A-4C are schematic diagrams illustrating another disclosed embodiment of an RF circuit in different operating modes, respectively; and

FIGS. 5A-5C are schematic diagrams illustrating another disclosed embodiment of an RF circuit in different operating modes, respectively.

### DETAILED DESCRIPTION

As mentioned above, an RF circuit (e.g., for RF applications, including millimeter wave (mmWave) wireless applications) can include a mixer. Those skilled in the art will recognize that a mixer can receive an initial radio frequency input signal and a local oscillator signal and can use the received signals to generate and output a mixed radio frequency output signal. A mixer can be a down-conversion mixer (also referred to herein as down-converter) or an up-conversion mixer (also referred to herein as up-converter). For example, in a down-converter the initial radio frequency input signal can be a high radio frequency input signal and the mixed radio frequency output signal can be a low or intermediate radio frequency output signal. In an up-converter the initial radio frequency input signal can be a low or intermediate radio frequency signal and the mixed radio frequency output signal can be a high radio frequency output signal.

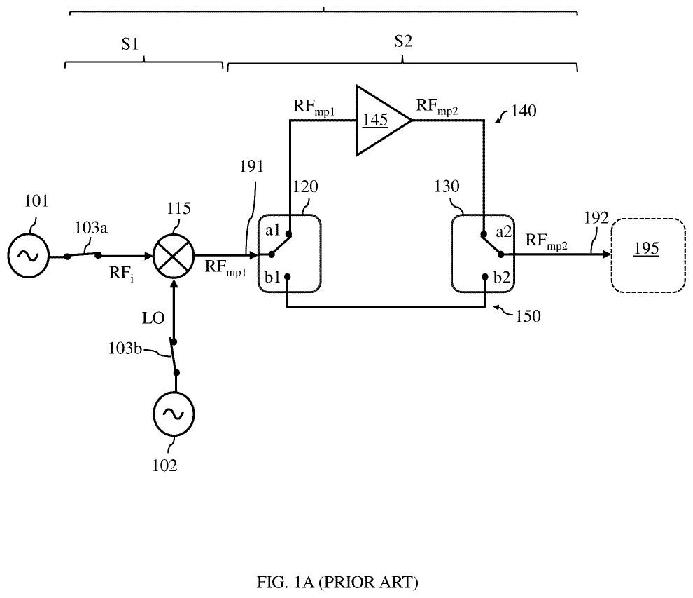

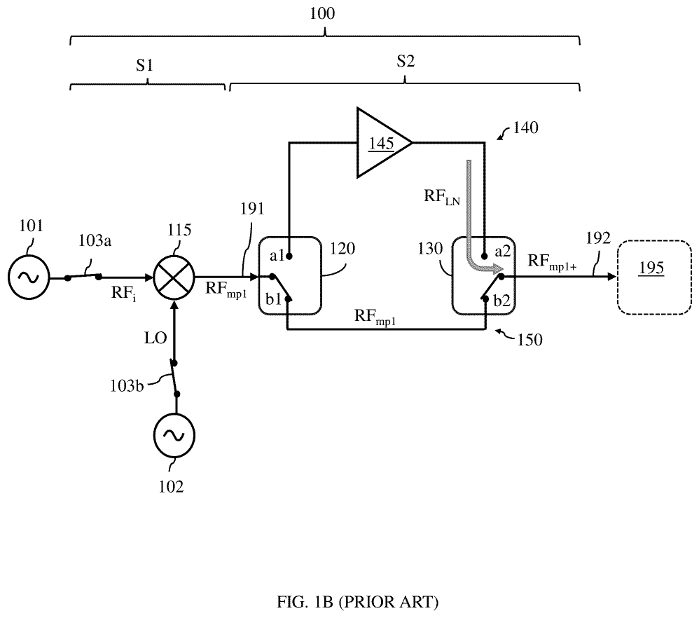

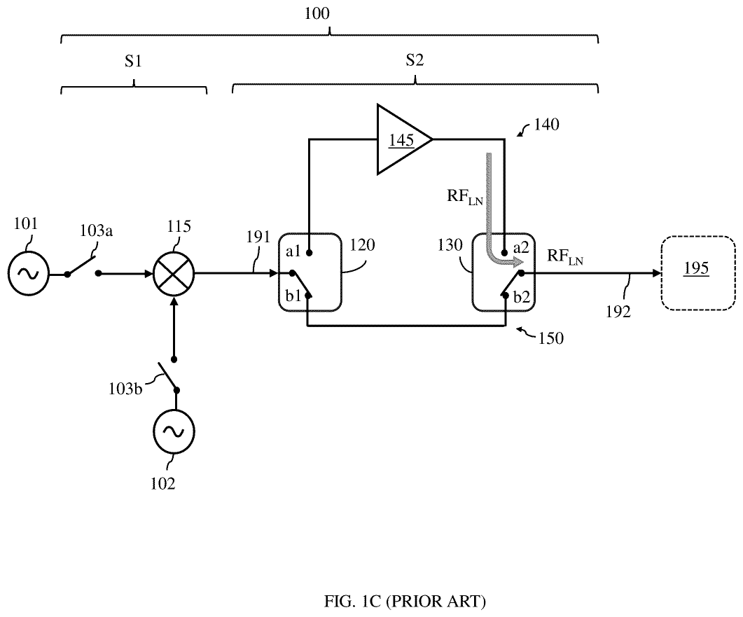

In some applications, an RF circuit 100 can include both a mixer stage (S1) and a power stage (S2) downstream of the mixer stage (S1) and can be designed to operate in three different modes (e.g., see FIGS. 1A-1C). These modes can include: a first signal mode during which a radio frequency signal at a high power level (mp2) should be output from an output terminal 192 to a device 195 (see FIG. 1A); a second signal mode during which a radio frequency signal at a low power level (mp1) should be output from output terminal 192 to device 195 (see FIG. 1B); and blocked signal mode during which all radio frequency signals are ideally blocked from being output to device 195 (see FIG. 1C).

More particularly, in RF circuit 100, mixer stage (S1) can include mixer 115. During the first and second signal modes, mixer 115 can be connected by switches 103a-103b to receive an initial radio frequency signal (RFᵢ) from a radio frequency signal source 101 and to receive a local oscillator signal (LO) from a local oscillator 102. Mixer 115 can use the received signals to generate and output a mixed radio frequency signal at a first power level (RFₘₚ₁). For example, in the case of an up-converter RFᵢ can be a low or intermediate radio frequency signal and RFₘₚ₁ can be a high radio frequency signal at a low power level. During the blocked signal mode, switches 103a-103b can disconnect the radio frequency signal source 101 and local oscillator 102 from mixer 115 so that mixer 115 does not output an RF signal.

The power stage (S2) can include an input terminal 191 and an output terminal 192. The power stage (S2) can also include a pair of signal paths: a power boosting path 140 including an amplifier 145; and a bypass path 150. The power stage (S2) can also include a pair of concurrently operable switches 120 and 130, which are controllable to: (a) connect the power boosting path 140 to the input and output terminals 191-192 during first signal mode to boost the power level of the mixed radio frequency signal from a first power level to a second power level that is higher than the first power level (e.g., from approximately −80.0 decibel milliwatts (dBmW) or less for RFₘₚ₁ to approximately 20.0 dBmW for RFₘₚ₂); and (b) connect the bypass path 150 to the input and output terminals 191-192 during the second signal mode and the blocked signal mode. However, even when the power boosting path 140 is disconnected from the input and output terminals 191-192 by switches 120-130 (i.e., during the second signal mode and the blocked signal mode), radio frequency noise can leak from amplifier 145 to output terminal 192. As a result, during the second signal mode, the power level of the mixed radio frequency signal received at the input terminal 191 from mixer 115 may be boosted at the output terminal 192 at least to some extent over the desired low power level (e.g., from approximately −80 dBmW or less for RFₘₚ₁ to approximately −60.0 or more for RFₘₚ₁₊). Thus, the actual dynamic power range of RF circuit 100 is relatively narrow (e.g., from approximately −60.0 decibel milliwatts (dBmW) or more for RFₘₚ₁₊ to approximately 20.0 dBmW for RFₘₚ₂) as opposed to having a desired range (e.g., of −80.0 dBmW or less to approximately 20.0 dBmW). Furthermore, during the blocked signal mode, the amount of RF noise leakage (RF_{LN}) seen at the output terminal 192 may exceed some desired level.

Device 195 could be a device under test (DUT). When undergoing different tests, DUT 195 may require receipt of RF signals at different frequency levels and/or at different power levels or may not require receipt of an RF signal at all. Specifically, DUT 195 may require: (1) receipt of RFₘₚ₁ during one or more tests; (2) receipt of RFₘₚ₁ during one or more tests; and (3) receipt of no RF signal during one or more tests. If, during testing of DUT 195 when RF circuit 100 is operating in the second signal mode, RFₘₚ₁ is inadvertently/undesirably boosted at output terminal 192 to RFₘₚ₁₊ due to RF_{LN} from amplifier 145 (see FIG. 1B), testing results may be inaccurate. Additionally, if, during testing of DUT 195 when RF circuit 100 is in the blocked signal mode, RF_{LN} at output terminal 192 is significantly less than the RF noise generated by the DUT 195 itself (e.g., during RF noise power density testing and noise figure measurements) (see FIG. 1C), testing results may also be inaccurate.

In view of the foregoing, disclosed herein are embodiments of a radio frequency (RF) circuit, which includes mixer and power stages, which can operate in a first signal mode (e.g., a high power signal mode), a second signal mode (e.g., a low power signal mode), and a blocked signal mode. The RF circuit is also configured to exhibit a wide dynamic power range, low RF leakage noise (RF_{LN}) and thermal stability. In each of the embodiments, the power stage can include a power boosting path and a bypass path. The power boosting path can include a first amplifier and a second amplifier connected in series. In some embodiments, the second amplifier can be switchable between an on state and an off state depending upon the mode. For example, the second amplifier can be in the on state during the first signal mode when power boosting is enabled and in the off state during the second signal mode or a blocked signal mode when power boosting is disabled. By placing the second amplifier in the off state when power boosting is disabled and the desired output is either a low power radio frequency signal or no radio frequency signal, leakage of radio frequency noise from the second amplifier to the output terminal is prevented. In alternative embodiments, instead of disabling the second amplifier to prevent leakage of radio frequency noise to the output terminal, the power stage can include a variable attenuator (the location of which varies depending upon the specific embodiment, as discussed below) and the attenuation state of the variable attenuator can be switchable depending upon the mode to achieve similar results. That is, the variable attenuator can be in a first attenuation state during the first signal mode when power boosting is enabled and in a second attenuation state that is higher than the first attenuation state when the desired output is either a low power radio frequency signal or little to no radio frequency signal.

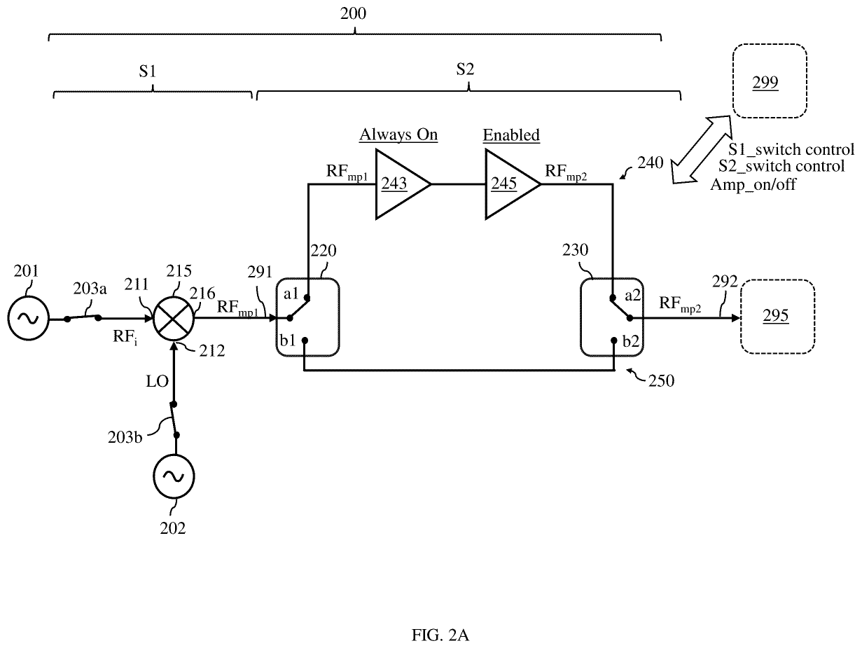

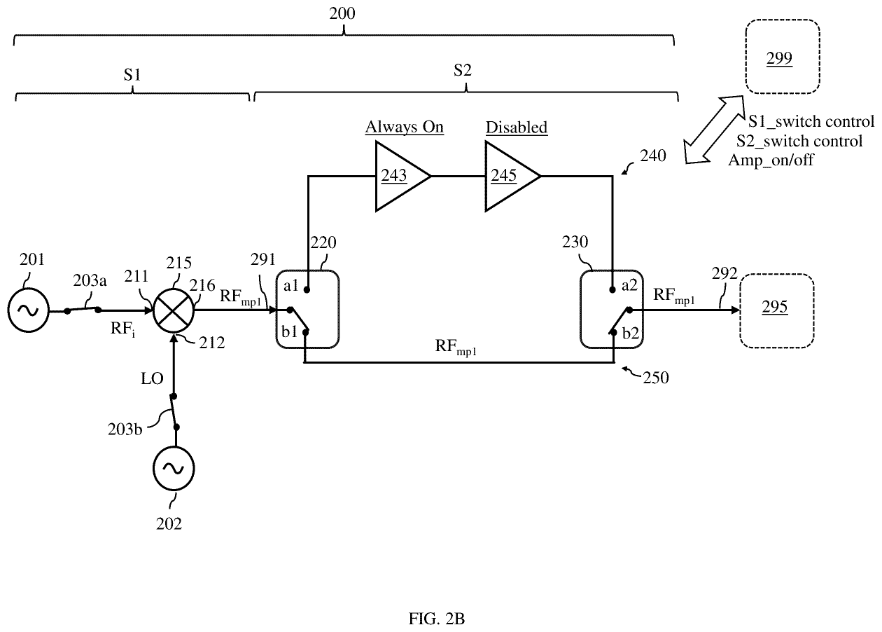

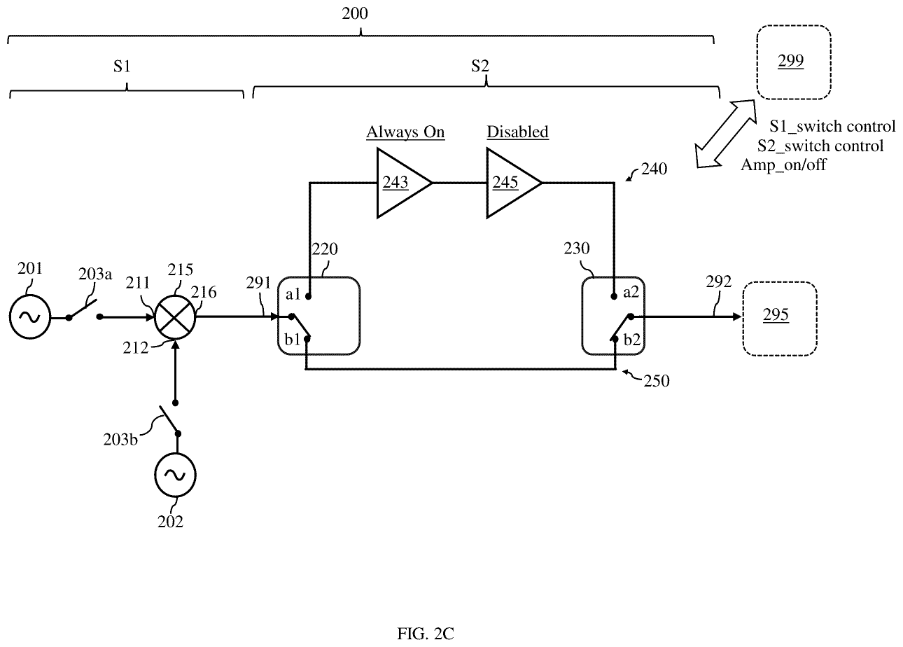

FIGS. 2A-2C are schematic diagrams illustrating disclosed embodiments of an RF circuit 200. RF circuit 200 can include control circuitry 299 and can be selectively operable in any of three different modes in response to control signals from control circuitry 299. As discussed in greater detail below, these modes can include: a first signal mode (also referred to herein as a high power mode) (see FIG. 2A); a second signal mode (also referred to herein as a low power mode) (see FIG. 2B); and blocked signal mode (see FIG. 2C). RF circuit 200 can further include, in communication with the control circuitry 299, a mixer stage (S1) and a power stage (S2) downstream of mixer stage (S1).

Mixer stage (S1) can include a mixer 215. Mixer 215 can include a first input node 211, a second input node 212, and an output node 216 (which is electrically connected to an input terminal of power stage (S2)). Mixer stage (S1) can further include first and second mixer stage switches 203a-203b. First mixer stage switch 203a can be electrically connected between a radio frequency signal source 201 and first input node 211, whereas second mixer stage switch 203b can be electrically connected between a local oscillator 202 and second input node 212. First and second mixer stage switches can be, for example, single-pole single-throw (SPST) switches. First and second mixer stage switches 203a-203b can be controlled by a same mixer stage switch control signal (S1_switch control) (e.g., from control circuitry 299). The state of S1_switch control can be selectively switched to cause the first and second mixer stage switches 203a-203b to close or open concurrently depending upon the mode of operation of RF circuit 200.

For example, when RF circuit 200 switches to either the first signal mode or the second signal mode, the state of S1_switch control can cause first and second mixer stage switches 203a-203b to concurrently close, and thereby connect first input node 211 of mixer 215 to radio frequency signal source 201 to receive an initial radio frequency signal (RFᵢ) and second input node 212 to local oscillator 202 to receive a local oscillator signal (LO). As a result, mixer 215 is enabled. It should be noted that in some embodiments, mixer 215 can be an up-converter (i.e., an up-conversion mixer). In these embodiments, RFᵢ is at a low or intermediate radio frequency level and mixer 215 uses (i.e., is configured to use) LO to shift RFᵢ to a high radio frequency level. That is, the mixer 215 is configured to mix LO and RFᵢ in order to generate and output (at output node 216 and to input terminal 291 of power stage (S2)) a mixed radio frequency signal (RFₘ) and, particularly, an up-converted RF signal at a higher frequency than RFᵢ. Alternatively, mixer 215 could be a down-converter (i.e., a down-conversion mixer). In these embodiments, RFᵢ is at high radio frequency level and mixer 215 uses (i.e., is configured to use) LO to shift RFᵢ to a low radio frequency level. That is, mixer 215 is configured to mix LO and RFᵢ in order to generate and output (at output node 216) a mixed radio frequency signal (RFₘ) and, particularly, a down-converted RF signal at a lower frequency than RFᵢ. Mixers including both up-converters and down-converters are well known in the art and, thus, the details thereof have been omitted from the specification in order to allow the reader to focus on the salient aspects of the disclosed embodiments. In any case, when output at output node 216, this mixed radio frequency signal can be at a first power level (p1) and, particularly, at a relatively low power level (e.g., see low power mixed radio frequency signal (RFₘₚ₁)). In some embodiments, this p1 can be within the range of −70.0 to −100.0 decibels per milliwatt (dBmW) (e.g., at approximately −85.0 dBmW).

Contrarily, when RF circuit 200 switches to the blocked signal mode, the state of S1_switch control can switch to cause first and second mixer stage switches 203a-203b to concurrently open, and thereby disconnect first input node 211 from radio frequency signal source 201 and disconnect second input node 212 from local oscillator 202. As a result, mixer stage (S1) is effectively disabled (i.e., RFₘₚ₁ is not generated and output to the input terminal 291 of power stage (S2)).

Power stage (S2) can include input terminal 291 (which, as mentioned above, is electrically connected to output node 216 of mixer 215), and an output terminal 292. Power stage (S2) can further include: a power boosting (PB) path 240 (including a first amplifier 243 and a second amplifier 245 connected in series) and a bypass (BP) path 250. First amplifier 243 can be, for example, a driver amplifier (e.g., a low noise amplifier (LNA)). For purposes of this disclosure, an LNA refers to an electronic device that can amplify a low power signal without significantly degrading its signal-to-noise ratio (SNR). Second amplifier 245 can be, for example, a power amplifier (PA). For purposes of this disclosure, a PA refers to an electronic device that can boost (i.e., increase) the power level of a received signal. LNAs and PAs are well known in the art and, thus, the details thereof have been omitted from this specification in order to allow the reader to focus on the salient aspects of the disclosed embodiment.

In any case, within PB path 240 of RF circuit 200, second amplifier 245 can be in either an on state (i.e., enabled) or an off state (i.e., disabled) depending on the mode of operation of the RF circuit 200 and, for example, as controlled by an amplifier on/off control signal (amp_on/off) from control circuitry 299. In some embodiments, first amplifier 243 can be in an always-on state (i.e., continuously powered on/enabled), as illustrated. By maintaining the first amplifier 243 in the always-on state, thermal fluctuations within RF circuit 200 are minimized. However, it should be understood that the figures are not intended to be limiting and that in alternative embodiments first amplifier 243 could also be controlled by amp_on/off and enabled/disabled concurrently with second amplifier 245.

Power stage (S2) can further include first and second power stage switches 220 and 230.

First and second power stage switches 220 and 230 can be, for example, single-pole double-throw (SPDT) switches. For example, first power stage switch 220 can have an input node, which is continuously electrically connected to input terminal 291 (and thereby to the output node 216 of mixer 215) and can further have a pair of output nodes, which are electrically connected to PB path input node (a1) and BP path input node (b1), respectively. Second power stage switch 230 can have a pair of input nodes, which are electrically connected to PB path output node (a2) and BP path output node (b2), respectively, and an output node, which is continuously electrically connected to output terminal 292. First and second power stage switches 220 and 230 can be controlled by a same power stage switch control signal (S2_switch control) (e.g., from control circuitry 299). The state of S2_switch control can be selectively switched to cause the first and second power stage switches 220 and 230 to: concurrently connect opposite ends (i.e., a1 and a2) of PB path 240 to input terminal 291 and output terminal 292, respectively; concurrently connect opposite ends (i.e., b1 and b2) of BP path 250 to input terminal 291 and output terminal 292, respectively, or, optionally, completely disconnect both PB path 240 and BP path 250 from input and output terminals 291-292, depending upon the mode of operation of RF circuit 200.

For example, as mentioned above, in the first signal mode, RFₘₚ₁ is output by mixer stage (S1) to input terminal 291 of power stage (S2). Additionally, in first signal mode, the state of S2_switch control received from control circuitry 299 can cause first and second power stage switches 220-230 to concurrently, electrically connect opposite ends (i.e., a1 and a2) of PB path 240 to input terminal 291 and output terminal 292, respectively. Furthermore, the state of amp_on/off received from control circuitry 299 can cause second amplifier 245 to switch to the on state (i.e., to be enabled). As a result, RFₘₚ₁ will be processed by first amplifier 243 and second amplifier 245 in PB path 240 so that the power level of the received mixed radio frequency signal from mixer 215 is boosted from the first power level (p1) to a second power level (p2), which is higher than the first power level. In some embodiments, this second power level could be in the range of 10-30 dBmW (e.g., at approximately 20 dBmW). In this case, a mixed radio frequency signal at p2 (RFₘₚ₂) is output at output terminal 292.

As mentioned above, in the second signal mode, RFₘₚ₁ is also output by mixer stage (S1) to input terminal 291 of power stage (S2). Additionally, in the second signal mode, the state of S2_switch control received from control circuitry 299 can cause first and second power stage switches 220-230 to concurrently, electrically connect opposite ends (i.e., b1 and b2) of BP path 250 to input terminal 291 and output terminal 292, respectively, so that RFₘₚ₁ is passed to output terminal 292 without being power boosted (i.e., so that power boosting is disabled). Furthermore, the state of amp_on/off received from control circuitry 299 can cause second amplifier 245 switch to the off state (i.e., to disable second amplifier 245). Placing second amplifier 245 in the off state when mixer 215 is enabled but power boosting is disabled, eliminates any leakage of radio frequency noise from second amplifier 245 to output terminal 292. As a result, any inadvertent and undesirable boosting of RFₘₚ₁ at output terminal 292 is prevented (i.e., RFₘₚ₁ is output from output terminal 292).

Also, as mentioned above, in the blocked signal mode, mixer stage (S1) is effectively disabled (i.e., mixer 215 does not output an RF signal to the power stage (S2)). Additionally, in the blocked signal mode, the state of S2_switch control received from control circuitry 299 can cause first and second power stage switches 220-230 to concurrently, electrically connect opposite ends (i.e., b1 and b2) of BP path 250 to input terminal 291 and output terminal 292, respectively, or, optionally, disconnect both PB path 240 and BP path 250 from input terminal 291 and output terminal 292. Thus, power stage (S2) is also effectively disabled. Furthermore, the state of amp_on/off received from control circuitry 299 can cause second amplifier 245 switch to the off state (i.e., to also specifically disable second amplifier 245). Placing second amplifier 245 in the off state when both mixer stage (S1) and power stage (S2) are effectively disabled, eliminates any leakage of radio frequency noise from second amplifier 245 to output terminal 292. As a result, any inadvertent and undesirable radio frequency noise signal (RF_{LN}) at output terminal 292 is prevented (e.g., essentially no radio frequency signals are output to output terminal 292).

Control circuitry 299 for providing control signals to an RF circuit including, but not limited to, control signals for selectively controlling the operation of various different types of switches are known in the art. Thus, the details thereof have been omitted from this specification in order to allow the reader to focus on the salient aspects of the disclosed embodiments.

Configured as described above, RF circuit 200 may exhibit a relatively large dynamic power range as compared to the dynamic power range exhibited by the RF circuit 100 of FIGS. 1A-1C. That is, as mentioned above with regards to RF circuit 200, the actual dynamic power range may be relatively narrow (e.g., from approximately −60.0 dBmW or more for RFₘₚ₁₊ to approximately 20.0 dBmW for RFₘₚ₂). However, in RF circuit 200, the dynamic power range may be relatively wide (e.g., over approximately 100 dB) and, particularly, extending from first power level (p1) to second power level (p2) (e.g., from −85.0 dBmW for RFₘₚ₁ output during the low power signal mode to approximately 20.0 dBmW for RFₘₚ₂ output during the high power signal mode).

It should be noted that output terminal 292 of RF circuit 200 could be electrically connected to a device 295 so that device 295 can receive and process the various RF signals at output terminal 292. In some embodiments, RF circuit 200 could be a discrete module and device 295 could be a DUT, which is electrically connected (e.g., via a cable) to output terminal 292. When undergoing different tests, DUT 295 may require receipt of RF signals at different frequency levels and/or at different power levels or may not require receipt of an RF signal at all. For example, DUT 295 may require: (1) receipt of RFₘₚ₁ during one or more tests; (2) receipt of RFₘₚ₂ during one or more tests; and (3) receipt of no RF signal during one or more tests. Because RFₘₚ₁ will not be inadvertently boosted at output terminal 292 due to radio frequency noise leakage during the second signal mode (i.e., the low power signal mode) (see FIG. 2B), the accuracy of the results of tests on DUT 295 that require an RF signal at p1 will be improved as compared to the accuracy of the results of such tests when performed using the RF circuit 100 of FIGS. 1A-1C. Additionally, because radio frequency leakage noise will not be output at output terminal 292 during the blocked signal mode (see FIG. 2C), the accuracy of the results of tests on DUT 295, such as RF noise power density testing or noise figure measurements, that require little to no RF signal will also be improved as compared to the accuracy of the results of such tests when performed using the RF circuit 100 of FIGS. 1A-1C.

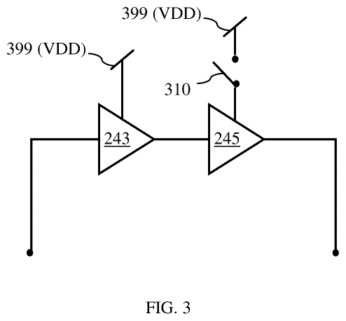

FIG. 3 is schematic diagram illustrating one example of a technique that can be used for maintaining first amplifier 243 in an always-on state and selectively switching second amplifier 245 between the on state (during the first signal mode) or off state (during the second signal mode or blocked signal mode). In this example, RF circuit 200 includes a positive supply voltage rail 399 at a positive supply voltage (VDD). First amplifier 243 can be electrically connected to positive supply voltage rail 399 so as to continuously receive (i.e., be powered by) VDD. Thus, first amplifier 243 is continuously enabled/powered on (i.e., in an always-on state). RF circuit 200 can include an additional switch 310 (e.g., a direct current (DC) power switch), which is connected between positive supply voltage rail 399 and second amplifier 243. In this example, switch 310 can be selectively controlled (e.g., by amp_on/off from control circuitry 299). That is, depending upon the state of amp_on/off, switch 310 can be closed to electrically connect the positive supply voltage rail 399 to second amplifier 245 (i.e., so that the second amplifier 245 is switched on) or it can be opened to disconnect the positive supply voltage rail 399 from second amplifier 245 (i.e., so that the second amplifier 245 is switched off).

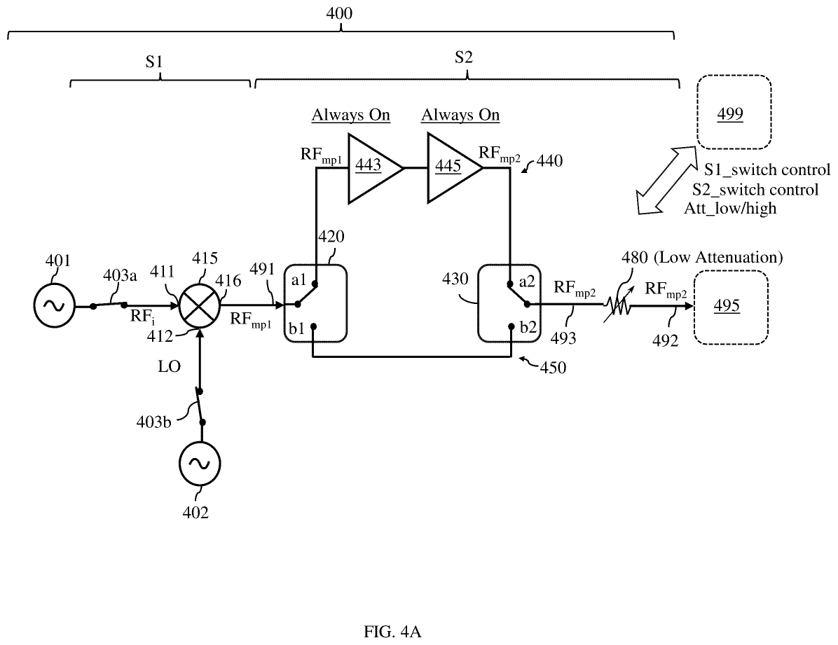

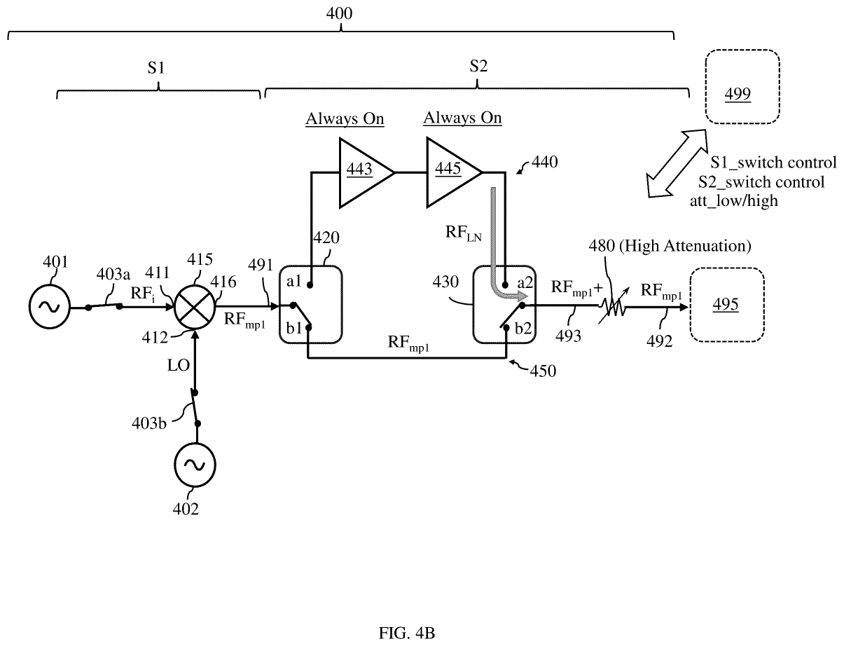

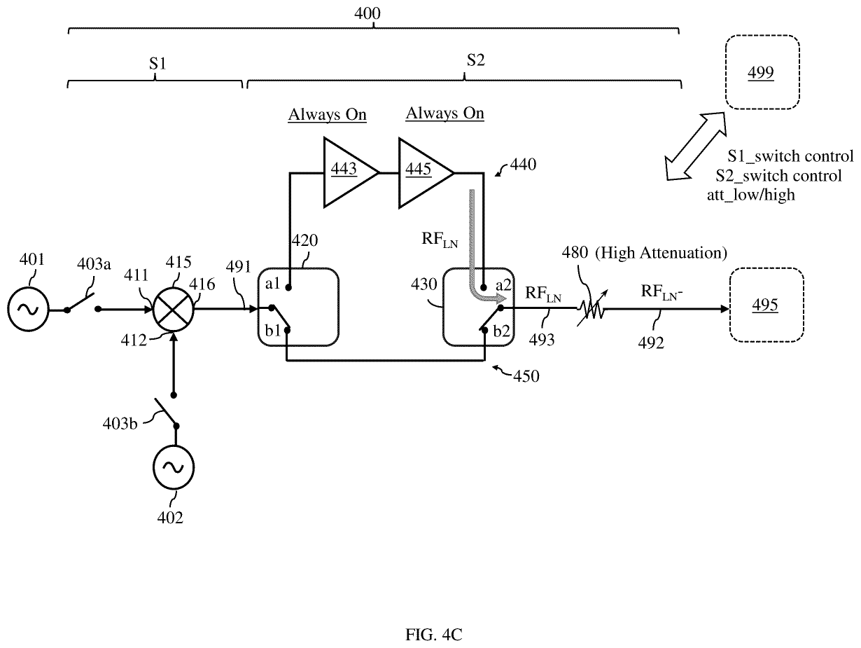

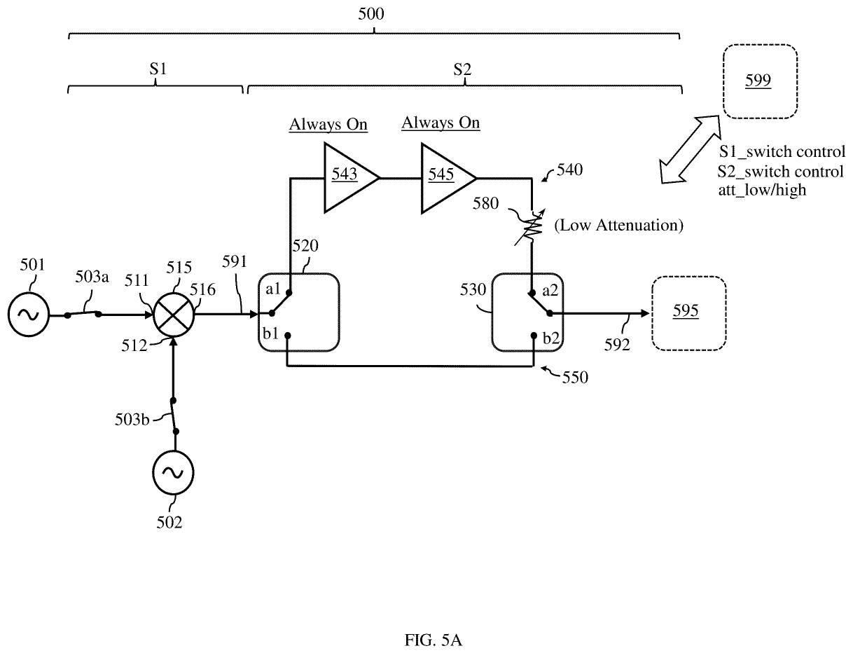

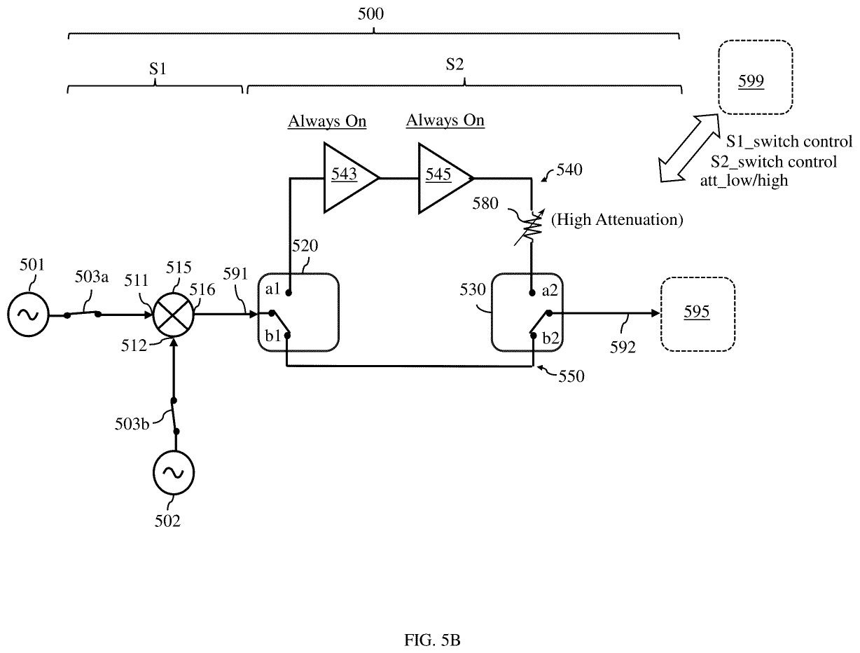

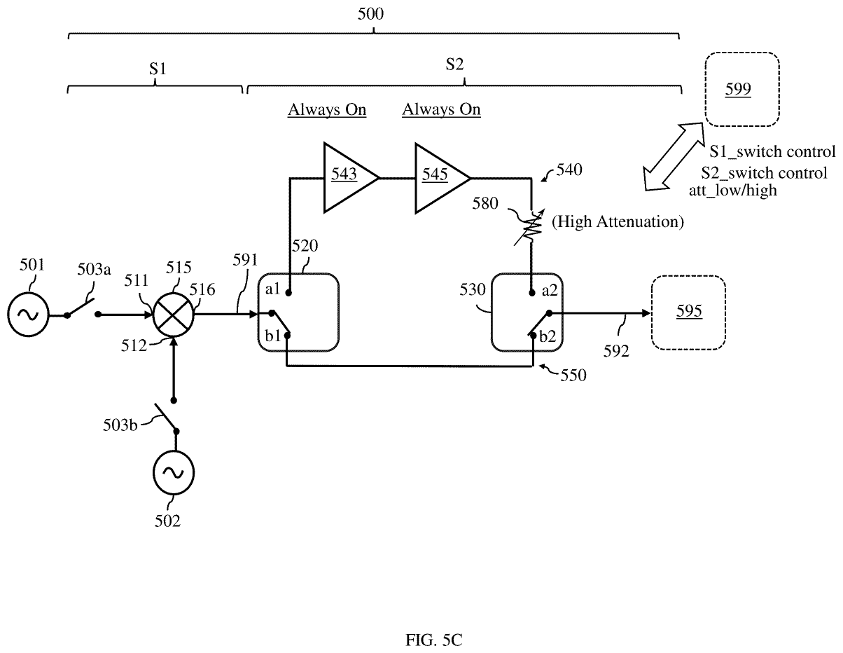

FIGS. 4A-4C are schematic diagrams illustrating disclosed embodiments of an RF circuit 400 and FIGS. 5A-5C are schematic diagrams illustrating disclosed embodiments of an RF circuit 500. In each of these RF circuits 400, 500, as discussed below, a variable attenuator 480, 580 is employed to control RF leakage noise at the output terminal 492, 592 (as opposed to disabling a power amplifier 445, 545 in a power boosting path 440, 540). More specifically, RF circuit 400, 500 can include control circuitry 499, 599 and can be selectively operable in any of three different modes in response to control signals from control circuitry 499, 599. As discussed in greater detail below, these modes can include: a first signal mode (also referred to herein as a high power mode) (see FIG. 4A or FIG. 5A); a second signal mode (also referred to herein as a low power mode) (see FIG. 4B or FIG. 5B); and blocked signal mode (see FIG. 4C or FIG. 5C). RF circuit 400, 500 can further include, in communication with the control circuitry 499, 599, a mixer stage (S1) and a power stage (S2) downstream of mixer stage (S1).

Mixer stage (S1) can be configured in essentially the same manner as the mixer stage in RF circuit 200 of FIGS. 2A-2C described above. That is, mixer stage (S1) can include a mixer 415, 515. Mixer 415, 515 can include a first input node 411, 511, a second input node 412, 512 and an output node 416, 516 (which is electrically connected to an input terminal of power stage (S2)). Mixer stage (S1) can further include first and second mixer stage switches 403a-403b, 503a-503b. First mixer stage switch 403a, 503a can be electrically connected between a radio frequency signal source 401, 501 and first input node 411, 511, whereas second mixer stage switch 403b, 503b can be electrically connected between a local oscillator 402, 502 and second input node 412, 512. First and second mixer stage switches can be, for example, single-pole single-throw (SPST) switches. First and second mixer stage switches 403a-403b, 503a-503b can be controlled by a same mixer stage switch control signal (S1_switch control) (e.g., from control circuitry 499, 599). The state of S1_switch control can be selectively switched to cause the first and second mixer stage switches 403a-403b, 503a-503b to concurrently close or concurrently open depending upon the mode of operation of RF circuit 400, 500.

For example, when RF circuit 400, 500 switches to either the first signal mode or the second signal mode, the state of S1_switch control can cause first and second mixer stage switches 403a-403b, 503a-503b to concurrently close and, thereby connect first input node 411, 511 of mixer 415, 515 to radio frequency signal source 401, 501 to receive an initial radio frequency signal (RFᵢ) and second input node 412, 512 to local oscillator 402, 502 to receive a local oscillator signal (LO). As a result, mixer 415, 515 is enabled. It should be noted that in some embodiments, mixer 415, 515 can be an up-converter (i.e., an up-conversion mixer). In these embodiments, RFᵢ is at a low or intermediate radio frequency level and mixer 415, 515 uses (i.e., is configured to use) LO to shift RFᵢ to a high radio frequency level. That is, the mixer 415, 515 is configured to mix LO and RFᵢ in order to generate and output (at output node 416, 516 and to input terminal 491, 591 of power stage (S2)) a mixed radio frequency signal (RFₘ) and, particularly, an up-converted RF signal at a higher frequency than RFᵢ. Alternatively, mixer 415, 515 could be a down-converter (i.e., a down-conversion mixer). In these embodiments, RFᵢ is at high radio frequency level and mixer 415, 515 uses (i.e., is configured to use) LO to shift RFᵢ to a low radio frequency level. That is, the mixer 415, 515 is configured to mix LO and RFᵢ in order to generate and output (at output node 416, 516) a mixed radio frequency signal (RFₘ) and, particularly, a down-converted RF signal at a lower frequency than RFᵢ. Mixers including both up-converters and down-converters are well known in the art and, thus, the details thereof have been omitted from the specification in order to allow the reader to focus on the salient aspects of the disclosed embodiments. In any case, when output at output node 416, 516, this mixed radio frequency signal can be at a first power level (p1) and, particularly, at a relatively low power level (e.g., see low power mixed radio frequency signal (RFₘₚ₁)). In some embodiments, this p1 can be within the range of −70.0 to −100.0 decibels per milliwatt (dBmW) (e.g., at approximately −85.0 dBmW).

Contrarily, when RF circuit 400, 500 switches to the blocked signal mode, the state of S1_switch control can switch to cause first and second mixer stage switches 403a-403b, 503a-503b to concurrently open and, thereby disconnect first input node 411, 511 from radio frequency signal source 401, 501 and disconnect second input node 412, 512 from local oscillator 402, 502. As a result, mixer stage (S1) is effectively disabled (i.e., RFₘₚ₁ is not generated and output to the input terminal 491 of power stage (S2)).

Referring specifically to RF circuit 400 of FIGS. 4A-4C, power stage (S2) can include input terminal 491 (which, as mentioned above, is electrically connected to output node 416 of mixer 415), an intermediate node 493, and an output terminal 492. Power stage (S2) can further include: a power boosting (PB) path 440 and a bypass (BP) path 450. PB path 440 can include a first amplifier 443 (e.g., a driver amplifier) and a second amplifier 445 (e.g., a power amplifier) connected in series. First amplifier 443 and second amplifier 445 can both be in always-on states (i.e., continuously powered on/enabled).

Power stage (S2) can further include first and second power stage switches 420 and 430.

First and second power stage switches 420 and 430 can be, for example, single-pole double-throw (SPDT) switches. For example, first power stage switch 420 can have an node, which is continuously electrically connected to input terminal 491 (and thereby to the output node 416 of mixer 415) and can further have a pair of output nodes, which are electrically connected to PB path input node (a1) and BP path input node (b1), respectively. Second power stage switch 430 can have a pair of input nodes, which are electrically connected to PB path output node (a2) and BP path output node (b2), respectively, and an output node, which is continuously electrically connected to intermediate node 493. First and second power stage switches 420 and 430 can be controlled by a same power stage switch control signal (S2_switch control) (e.g., from control circuitry 499). The state of S2_switch control can be selectively switched to cause the first and second power stage switches 420 and 430 to: concurrently connect opposite ends (i.e., a1 and a2) of PB path 440 to input terminal 491 and intermediate node 493, respectively; concurrently connect opposite ends (i.e., b1 and b2) of BP path 450 to input terminal 491 and intermediate node 493, respectively, or, optionally, completely disconnect both PB path 440 and BP path 450 from input terminal 491 and intermediate node 493, depending upon the mode of operation of RF circuit 400.

Power stage (S2) can further include a variable attenuator 480 electrically connected between intermediate node 493 and output terminal 492. Variable attenuator 480 can be selectively operable (e.g., in response to an attenuation state control signal (att_low/high) from control circuitry 499) in at least two different attenuation states depending upon the mode of operation of RF circuit 400. These attenuation states can include a first attenuation state (also referred to herein as a low attenuation state) and a second attenuation state (also referred to herein as a high attenuation state) that is higher than the first attenuation state. Variable attenuators can be implemented, for example, using a variety of different types of devices (e.g., microwave dielectric absorber attenuators, PIN diode attenuators, variable resistor attenuator, etc.). Those skilled in the art will recognize that different types of variable attenuators may be preferrable for use with different RF bands and applications. For example, for mmWave wireless applications, microwave dielectric absorber attenuators or PIN diode attenuators may be preferrable, whereas for low frequency applications, variable resistor attenuators may be preferrable. In any case, variable attenuators (e.g., microwave dielectric absorber attenuators, PIN diode attenuators, variable resistor attenuators, etc.) are known in the art and, thus, the details thereof have been omitted from the specification in order to allow the reader to focus on the salient aspects of the disclosed embodiments. Furthermore, it should be understood that the different types of variable attenuators mentioned above are provided for illustration purposes and are not intended to be limiting. Alternatively, any now known or subsequently developed variable attenuator that is suitable for use in the circuit (e.g., depending on the RF band and application) may be included in power stage (S2).

In operation, as mentioned above, in the first signal mode, RFₘₚ₁ is output by mixer stage (S1) to input terminal 491 of power stage (S2). Additionally, in first signal mode, the state of S2_switch control received from control circuitry 499 can cause first and second power stage switches 420-430 to concurrently, electrically connect opposite ends (i.e., a1 and b1) of PB path 440 to input terminal 491 and intermediate node 493, respectively. Furthermore, the state of att_low/high received from control circuitry 499 can cause variable attenuator 480 to switch to the first attenuation state (i.e., the low or no attenuation state). As a result, RFₘₚ₁ will be processed by first amplifier 443 and second amplifier 445 in PB path 440 so that the power level of the received mixed radio frequency signal from mixer 415 is boosted from the first power level (p1) to a second power level (p2), which is higher than the first power level. In some embodiments, this second power level could be in the range of 10-30 dBmW (e.g., at approximately 20 dBmW). Thus, a mixed radio frequency signal at p2 (RFₘₚ₂) is output to intermediate node 493 and further passes through variable attenuator 480 to output terminal 492 with little to no attenuation so that the radio frequency output signal output from the output terminal 492 has essentially the same second power level (p2) (i.e., RFₘₚ₂ is output from output terminal 492).

As mentioned above, in the second signal mode, RFₘₚ₁ is also output by mixer stage (S1) to input terminal 491 of power stage (S2). Additionally, in the second signal mode, the state of S2_switch control received from control circuitry 499 can cause first and second power stage switches 420-430 to concurrently, electrically connect opposite ends (i.e., b1 and b2) of BP path 450 to input terminal 491 and intermediate node 493, respectively, so that RFₘₚ₁ is passed to intermediate node 493. In this case, radio frequency noise leakage (RF_{LN}) from second amplifier 445 will cause RFₘₚ₁ on intermediate node 493 to be power boosted to some extent (e.g., to RFₘₚ₁₊). However, the state of att_low/high received from control circuitry 499 can cause variable attenuator 480 to switch to the second attenuation state (i.e., the high attenuation state). Placing variable attenuator 480 in the high attenuation state results in attenuation of RFₘₚ₁₊ reducing the power level back down (e.g., back down to approximately the first power level (p1) and, thus, ideally RFₘₚ₁ is output at output terminal 492). One disadvantage of this technique is that the amount of attenuation that occurs when variable attenuator 480 is in the high attenuation state may result in the actual power level of the RF signal output at the output terminal being less than that of RFₘₚ₁ (e.g., RFₘₚ₁₋).

Also, as mentioned above, in the blocked signal mode, mixer stage (S1) is effectively disabled (i.e., mixer 415 does not output an RF signal to the power stage (S2)). Additionally, in the blocked signal mode, the state of S2_switch control received from control circuitry 499 can cause first and second power stage switches 420-430 to concurrently, electrically connect opposite ends (i.e., b1 and b2) of BP path 450 to input terminal 491 and intermediate node 493, respectively, or, optionally, disconnect both PB path 440 and BP path 450 from input terminal 491 and intermediate node 493. In this case, radio frequency noise leakage (RF_{LN}) from second amplifier 445 will still pass to intermediate node 493. However, the state of att_low/high received from control circuitry 499 can cause variable attenuator 480 to switch to the second attenuation state (i.e., the high attenuation state). Placing variable attenuator 480 in the high attenuation state results in attenuation of RF_{LN} reducing the power level of RF_{LN} down below some predetermined level. Thus, reduced-power radio frequency noise leakage (RF_{LN-}) or even no radio frequency noise leakage is output at the output terminal 492.

Like RF circuit 400 of FIGS. 4A-4C, RF circuit 500 of FIGS. 5A-5C can include a variable attenuator 580. However, variable attenuator 580 can be placed within (as opposed to outside) power boosting path 540 to prevent attenuation of the RFₘₚ₁ (i.e., to prevent outputting of RFₘₚ₁₋). More particularly, RF circuit 500 can include a power stage (S2) including an input terminal 591 (which, as mentioned above, is electrically connected to output node 516 of mixer 515) and an output terminal 592. Power stage (S2) can further include: a power boosting (PB) path 540 and a bypass (BP) path 450.

PB stage 540 can include: a first amplifier 543 (e.g., a driver amplifier), a second amplifier 545 (e.g., a power amplifier); and a variable attenuator 580 connected in series. First amplifier 543 and second amplifier 545 can be in always-on states (i.e., continuously powered on/enabled). Variable attenuator 580 can be selectively operable (e.g., in response to an attenuation state control signal (att_low/high) from control circuitry 599) in at least two different attenuation states depending upon the mode of operation of RF circuit 500. These attenuation states can include a first attenuation state (also referred to herein as a low attenuation state) and a second attenuation state (also referred to herein as a high attenuation state) that is higher than the first attenuation state. As discussed in detail above with regard to variable attenuator 480 of FIGS. 4A-4C, various different types of variable attenuators are known in the art (e.g., microwave dielectric absorber attenuators, PIN diode attenuators, variable resistor attenuator, etc.). It should be understood that any suitable now known or subsequently developed type of variable attenuator could be incorporated into power stage (S2) as variable attenuator 580.

Power stage (S2) can further include first and second power stage switches 520 and 530.

First and second power stage switches 520 and 530 can be, for example, single-pole double-throw (SPDT) switches. For example, first power stage switch 520 can have an input node, which is continuously electrically connected to input terminal 591 (and thereby to the output node 516 of mixer 515) and can further have a pair of output nodes, which are electrically connected to PB path input node (a1) and BP path input node (b1), respectively. Second power stage switch 530 can have a pair of input nodes, which are electrically connected to PB path output node (a2) and BP path output node (b2), respectively, and an output node, which is continuously electrically connected to output terminal 592. First and second power stage switches 520 and 530 can be controlled by a same power stage switch control signal (S2_switch control) (e.g., from control circuitry 599). The state of S2_switch control can be selectively switched to cause the first and second power stage switches 520 and 530 to: concurrently connect opposite ends (i.e., a1 and a2) of PB path 540 to input terminal 591 and output terminal 592, respectively; concurrently connect opposite ends (i.e., b1 and b2) of BP path 550 to input terminal 591 and output terminal 592, respectively, or, optionally, completely disconnect both PB path 440 and BP path 550 from input terminal 591 and output terminal 592, depending upon the mode of operation of RF circuit 500.

In operation, as mentioned above, in the first signal mode, RFₘₚ₁ is output by mixer stage (S1) to input terminal 591 of power stage (S2). Additionally, in first signal mode, the state of S2_switch control received from control circuitry 599 can cause first and second power stage switches 520-530 to concurrently, electrically connect opposite ends (i.e., a1 and b1) of PB path 540 to input terminal 591 and output terminal 592, respectively. Furthermore, the state of att_low/high received from control circuitry 599 can cause variable attenuator 580 to switch to the first attenuation state (i.e., the low or no attenuation state). As a result, RFₘₚ₁ will be processed by first amplifier 543 and second amplifier 545 in PB path 540 so that the power level of the received mixed radio frequency signal from mixer 515 is boosted from the first power level (p1) to a second power level (p2), which is higher than the first power level. In some embodiments, this second power level could be in the range of 10-30 dBmW (e.g., at approximately 20 dBmW). A resulting mixed radio frequency signal at p2 (RFₘₚ₂) is output through variable attenuator 580 (set for little or no attenuation) to output terminal 592 (e.g., so RFₘₚ₂ is output from output terminal 592).

As mentioned above, in the second signal mode, RFₘₚ₁ is also output by mixer stage (S1) to input terminal 591 of power stage (S2). Additionally, in the second signal mode, the state of S2_switch control received from control circuitry 599 can cause first and second power stage switches 520-530 to concurrently, electrically connect opposite ends (i.e., b1 and b2) of BP path 550 to input terminal 591 and output terminal 592, respectively, so that RFₘₚ₁ is passed to output terminal 592 (without passing through a variable attenuator). In this case, radio frequency noise leakage (RF_{LN}) from second amplifier 545 will pass through variable attenuator 580 (which is switched to the second attenuation state (i.e., the high attenuation state) in response to a change in state of att_low/high received from control circuitry 599. Placing variable attenuator 580 in the high attenuation state results in attenuation of RF_{LN} before it reaches the output terminal 592 and thus, RFₘₚ₁ from mixer 515 is output at output terminal 592. While this technique may reduce the dynamic power range to some extent, it prevents the power level of RFₘₚ₁ from being reduced.

Also, as mentioned above, in the blocked signal mode, mixer stage (S1) is effectively disabled (i.e., mixer 515 does not output an RF signal to the power stage (S2)). Additionally, in the blocked signal mode, the state of S2_switch control received from control circuitry 599 can cause first and second power stage switches 520-530 to concurrently, electrically connect opposite ends (i.e., b1 and b2) of BP path 550 to input terminal 591 and output terminal 592, respectively, or, optionally, disconnect both PB path 540 and BP path 550 from input terminal 591 and output terminal 592. In this case, radio frequency noise leakage (RF_{LN}) from second amplifier 545 is again attenuated by variable attenuator 580 in the second attenuation state (i.e., the high attenuation state). Placing variable attenuator 580 in the high attenuation state results in attenuation of RF_{LN} reducing the power level of RF_{LN} down below some predetermined level before leaving PB path 540. Thus, reduced power radio frequency noise leakage (RF_{LN-}) or even no radio frequency noise leakage is output at the output terminal 592.

Referring again to RF circuit 400 of FIGS. 4A-4C and RF circuit 500 of FIGS. 5A-5C, control circuitry 499, 599, respectively, for providing control signals to an RF circuit including, but not limited to, control signals for selectively controlling the operation of various types of switches and a variable attenuator (e.g., a variable resistor) are known in the art. Thus, the details thereof have been omitted from this specification in order to allow the reader to focus on the salient aspects of the disclosed embodiments.

Configured as described above, RF circuit 400, 500 may exhibit a relatively large dynamic power range as compared to the dynamic power range exhibited by the RF circuit 100 of FIGS. 1A-1C. That is, the actual dynamic power range may be relatively narrow (e.g., from approximately −60.0 dBmW or more for RFₘₚ₁₊ to approximately 20.0 dBmW for RFₘₚ₂). However, in RF circuit 400, the dynamic power range may be relatively wide (e.g., over approximately 100 dB) and, particularly, extending from first power level (p1) to the second power level (p2) (e.g., from −85.0 dBmW for RFₘₚ₁ output during the low power signal mode to approximately 20.0 dBmW for RFₘₚ₂ output during the high power signal mode). As discussed above, the dynamic power range of RF circuit 500 may be somewhat less than that of RF circuit 400 due to the placement of the variable attenuator 580.

It should be noted that, while RF circuit 400 of FIGS. 4A-4C and RF circuit 500 of FIGS. 5A-5C may have some disadvantages (e.g., additional insertion loss, additional size increase, additional noise at output terminal due to attenuation settings, etc.) as compared to RF circuit 200 of FIGS. 2A-2C, these circuits provide significant improvement, as discussed below, as compared to RF circuit 100 of FIGS. 1A-1C.

For example, output terminal 492, 592 of RF circuit 400, 500 could be electrically connected to a device 495, 595 so that device 495, 595 can receive and process the various RF signals output at output terminal 492, 592. In some embodiments, RF circuit 400, 500 could be a discrete module and device 495, 595 could be a DUT, which is electrically connected (e.g., via a cable) to output terminal 492, 592. When undergoing different tests, DUT 495, 595 may require receipt of RF signals at different frequency levels and/or at different power levels or may not require receipt of an RF signal at all. For example, DUT 495, 595 may require: (1) receipt of RFₘₚ₁ during one or more tests; (2) receipt of RFₘₚ₂ during one or more tests; and (3) receipt of little to no RF signal during one or more tests. Because of RF noise attenuation during the second signal mode (i.e., the low power signal mode) (see FIG. 4B or 5B), the accuracy of the results of test on DUT 495, 595 that require an RF signal at p1 will be improved as compared to the accuracy of the results of such tests when performed using RF circuit 100 of FIGS. 1A-1C. Additionally, because any radio frequency noise will be attenuated before being output at output to DUT 495, 595 during the blocked signal mode (see FIG. 4C or FIG. 5C), the accuracy of the results of tests on DUT 495, 595, such as RF noise power density testing or noise figure measurements, that require little to no RF signal will also be improved as compared to the accuracy of the results of such tests when performed using RF circuit 100 of FIGS. 1A-1C. Note: when testing of DUT 495, 595 includes RF noise power density testing or noise figure measurement during the blocked signal mode, the amount of RF noise attenuation by variable attenuator 480, 580 should be sufficient to ensure that any RF noise leakage output to DUT 495, 595 is below the level of noise produced by DUT 495, 595 itself in order to ensure accurate testing results.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a mixer stage; and
a power stage including:
an input terminal and an output terminal, wherein the input terminal is connected to the mixer stage;
a power boosting path including a first amplifier and a second amplifier connected in series;
a bypass path; and
first and second power stage switches concurrently operable to connect opposite ends of one of the power boosting path and the bypass path to the input terminal and the output terminal, respectively.

2. The structure of claim 1, wherein the first amplifier includes a driver amplifier and the second amplifier includes a power amplifier.

3. The structure of claim 1, wherein the first amplifier is continuously in an on state and wherein the second amplifier is switchable between an on state and an off state.

4. The structure of claim 3,
wherein the power stage further includes: a positive supply voltage rail; and an additional switch connected between the second amplifier and the positive supply voltage rail, and
wherein the additional switch is controllable to change states of the second amplifier between the on state and the off state.

5. The structure of claim 3,
wherein the structure is operable in any of a first signal mode, a second signal mode, and a blocked signal mode,
wherein, in first signal mode, the first and second power stage switches connect the opposite ends of the power boosting path to the input terminal and the output terminal, respectively, and the second amplifier is in the on state,
wherein, in the second signal mode, the first and second power stage switches connect the opposite ends of the bypass path to the input terminal and the output terminal, respectively, and the second amplifier is in the off state, and
wherein, in the blocked signal mode, the first and second power stage switches either connect the opposite ends of the bypass path to the input terminal and the output terminal, respectively, or disconnect the power boosting path and the bypass path from the input terminal and the output terminal, and the second amplifier is in the off state.

6. The structure of claim 5, wherein the mixer stage includes:
a mixer including a first input node, a second input node, and an output node, wherein the output node is connected to the input terminal of the power stage; and
first and second mixer stage switches connected between a radio frequency signal source and the first input node and between a local oscillator and the second input node.

7. The structure of claim 6,
wherein, in the first signal mode and in the second signal mode, the first and second mixer stage switches concurrently connect the first input node to the radio frequency signal source to receive an initial radio frequency signal and the second input node to the local oscillator to receive a local oscillator signal and the mixer uses the initial radio frequency signal and the local oscillator signal to generate and output a mixed radio frequency signal at the output node, and
wherein, in the blocked signal mode, the first and second mixer stage switches disconnect the radio frequency signal source and the local oscillator from the first input node and the second input node, respectively.

8. The structure of claim 7, wherein the mixed radio frequency has a higher frequency than the initial radio frequency signal.

9. The structure of claim 7,
wherein the mixed radio frequency signal is at a first power level when output from the output node of the mixer to the input terminal of the power stage,
wherein, in the first signal mode, the power boosting path boosts the mixed radio frequency signal to a second power level that is higher than the first power level and outputs the mixed radio frequency signal at the second power level to the output terminal, and
wherein, in the second signal mode, the bypass path outputs the mixed radio frequency signal at the first power level to the output terminal.

10. The structure of claim 9, wherein switching of the second amplifier to the off state prevents leakage of radio frequency noise from the second amplifier to the output terminal during the second signal mode and the blocked signal mode.

11. The structure of claim 1, wherein the output terminal is connected to a device.

12. A structure comprising:
a mixer stage; and
a power stage including:
an input terminal connected to the mixer stage;
an intermediate node;
an output terminal;
a power boosting path including a first amplifier and a second amplifier connected in series;
a bypass path;
first and second power stage switches concurrently operable to connect opposite ends of one of the power boosting path and the bypass path to the input terminal and the intermediate node, respectively; and
a variable attenuator connected between the intermediate node and the output terminal.

13. The structure of claim 12, wherein the first amplifier includes a driver amplifier and the second amplifier includes a power amplifier.

14. The structure of claim 12, wherein the variable attenuator is operable in at least a first attenuation state and a second attenuation state that is higher than the first attenuation state.

15. The structure of claim 14, wherein the variable attenuator includes any of a microwave dielectric absorber attenuator, a PIN diode attenuator, and a variable resistor attenuator.

16. The structure of claim 14,
wherein the structure is operable in any of a first signal mode, a second signal mode, and a blocked signal mode,
wherein, in first signal mode, the first and second power stage switches connect the opposite ends of the power boosting path to the input terminal and the intermediate node, respectively, and the variable attenuator is in the first attenuation state, and
wherein, in the second signal mode, the first and second power stage switches connect the opposite ends of the bypass path to the input terminal and the intermediate node, respectively, and the variable attenuator is in the second attenuation state, and
wherein, in the blocked signal mode, the first and second power stage switches either connect the opposite ends of the bypass path to the input terminal and the intermediate node, respectively, or disconnect the power boosting path and the bypass path from the input terminal and the intermediate node, and the variable attenuator is in the second attenuation state.

17. The structure of claim 16,
wherein the mixer stage includes:
a mixer including a first input node, a second input node, and an output node, wherein the output node is connected to the input terminal of the power stage; and
first and second mixer stage switches connected between a radio frequency signal source and the first input node and between a local oscillator and the second input node,
wherein the structure is operable in any of a first signal mode, a second signal mode, and a blocked signal mode,
wherein, in the first signal mode and in the second signal mode, the first and second mixer stage switches concurrently connect the first input node to the radio frequency signal source to receive an initial radio frequency signal and the second input node to the local oscillator to receive a local oscillator signal and the mixer uses the initial radio frequency signal and the local oscillator signal to generate and output a mixed radio frequency signal at the output node, and
wherein, in the blocked signal mode, the first and second mixer stage switches disconnect the radio frequency signal source and the local oscillator from the first input node and the second input node, respectively.

18. The structure of claim 17, wherein the mixed radio frequency signal has a higher frequency than the initial radio frequency signal.

19. The structure of claim 17,
wherein the mixed radio frequency signal is at a first power level when output from the output node of the mixer to the input terminal of the power stage,
wherein, in the first signal mode, the power boosting path boosts the mixed radio frequency signal to a second power level that is higher than the first power level and outputs the mixed radio frequency signal at the second power level to the intermediate node,
wherein, in the second signal mode, the bypass path outputs the mixed radio frequency signal at the first power level to the intermediate node, and
wherein switching of the variable attenuator to the second attenuation state attenuates any leakage of radio frequency noise from the second amplifier during the second signal mode and the blocked signal mode.

20. A structure comprising:
a mixer stage; and
a power stage including:
an input terminal and an output terminal, wherein the input terminal is connected to the mixer stage;
a power boosting path including a first amplifier, a second amplifier, and a variable attenuator connected in series;
a bypass path; and
first and second power stage switches concurrently operable to connect opposite ends of one of the power boosting path and the bypass path to the input terminal and the output terminal, respectively.
